(19) United States
(12) Patent Application Publication
(10) Pub. No.: US 2015/0318666 A1
(43) Pub. Date: Nov. 5, 2015

(54) VERTICAL-CAVITY SURFACE-EMITTING TRANSISTOR LASER, T-VCSEL AND METHOD FOR PRODUCING THE SAME

(71) Applicants: Mattias HAMMAR, Stockholm (SE); Rickard MARCKS VON WÜRTEMBERG, Stockholm (SE); Xingang YU, Solna (SE)

(72) Inventors: Mattias HAMMAR, Stockholm (SE); Rickard MARCKS VON WÜRTEMBERG, Stockholm (SE); Xingang YU, Solna (SE)

(21) Appl. No.: 14/648,993

(22) PCT Filed: Dec. 4, 2013
(86) PCT No.: PCT/SE2013/051451

§ 371 Date: Jun. 2, 2015

Related U.S. Application Data
(60) Provisional application No. 61/733,441, filed on Dec. 5, 2012.

(51) Int. Cl. H01S 5/062; H01S 5/187; H01S 5/02; H01S 5/30; H01S 5/042; H01S 5/343; H01S 5/183

(52) U.S. Cl. CPC H01S 5/06203; H01S 5/34313; H01S 5/187; H01S 5/1835; H01S 5/3095; H01S 5/18361; H01S 5/18369; H01S 5/0421; H01S 5/0206

(57) ABSTRACT

It is provided a transistor vertical-cavity surface-emitting laser, T-VCSEL comprising: a collector section (13) comprising a bottom substrate (11) and a base contacting layer (172), defining the collector region, an emitter section (14) and a base section (16), arranged between the emitter section (14) and the collector section (13), and comprising a collector contacting layer (171) and a light emitting active layer (17), arranged between layers (15, 15′) of a base material. The emitter section (14) comprises a current confining blocking layer (110) that comprises a first material layer (112), having a first type of doping and comprising a current confining means (111, 211) and a second material layer (19), defining the emitter region, having a second type of doping and being provided on the base side of the material layer (112). This design allows electrical carriers injected from the emitter (14) to flow through the current confining blocking layer (110) confined by the current confining means (111) to arrive at the base (16) and activate the light emitting active layer (17). Methods for fabricating T-VCSELs according to these designs are also provided.

### TECHNICAL FIELD

The present invention generally relates to a vertical-cavity surface-emitting transistor laser (T-VCSEL) and methods for producing the same. It also covers the use of the same in applications such as high-speed data communication.

### BACKGROUND

The transistor laser (TL) is a fundamentally new device type that since its first demonstration in 2005 has received significant interest [1]. Unlike the monolithic integration of a transistor and a laser diode on the same chip where the transistor performs as the driver of the laser [2], the TL relies on the fusion of the two components into a single device where the base recombination is used to provide stimulated emission. Due to an altered carrier dynamics in the base/cavity region and the three-terminal configuration, the TL has a number of attractive properties and potential advantages compared to conventional diode lasers, many of which have already been demonstrated and that can be briefly summarized as follows:
An ultrafast radiative recombination lifetime allowing for resonance-free frequency response (and thereby suppression of relaxation oscillations and reduced turn-on delay) [3]; enhancement of the modulation bandwidth [4,5,6,7,8]; and reduction of the relative intensity noise (RIN) close to the shot-noise limit [9].
Collector current-feedback allowing for the elimination of the monitor photodiode and for simplified power stabilization circuitry [10]; enhanced modulation bandwidth [11]; and a reduction in the 3rd order intermodulation distortion (IMD) [12]. The improved linearity may also allow multi-level modulation formats for digital applications [13].
Transistor-based design techniques and modes of operation allowing for voltage-driven operation (leading to simplified or even eliminated driver electronics) [14]; common-emitter or common-base configurations to engineer the frequency response and overall gain [15]; and increased-flexibility matching network designs or ultra-compact negative-resistance oscillators, mixers, etc., for analog applications [16].

Transistor lasers have received significant attention during recent years. Based on the monolithic integration of a heterojunction bipolar transistor (HBT) in a semiconductor laser they provide a number of unique properties as compared to conventional diode lasers, see ref [1, 3]. A particularly attractive feature is the potential for increased laser modulation bandwidth due to the altered charge dynamics in the base region, see ref [6]. Given the growing demand for broadband capacity in optical communication networks this may find important applications. Single-channel data rates of 40 Gbit/s and beyond are, e.g., presently considered for both local area networks and interconnects. Due to the tough requirements on cost- and power-efficiency, vertical-cavity surface-emitting lasers (VCSELs) are the preferred light-sources for these applications. Whereas VCSELs have been demonstrated with 3 dB-bandwidth of 28 GHz, see ref [17] and VCSEL-based optical links with modulation speeds up to 55 Gbit/s [18], this is approaching fundamental limits. To reach such high and even higher modulation rates over an extended temperature range and with sufficient output power, radically new design concepts are required. Transistor-VCSELs (T-VCSELs) and their potential for high-speed modulation were evaluated numerically by Shi et al. [14], and very recently the first experimental demonstration of a T-VCSEL at low temperature was reported [20], including the voltage controlled operation of such lasers [21].

The T-VCSEL combines the functionality and performance advantages of transistor lasers with the inherent advantages of conventional diode-type VCSELs widely used in optical communication networks, such as cost- and power-efficiency, option for two-dimensional arrays, circular beam profile, etc. Hence, it provides the potential for low-cost, low-power consumption digital and analogue applications with improved performance, simplified monitor and driver designs, as well as options for transistor-based circuit design techniques.

Whereas VCSELs with 3 dB-bandwidth of 28 GHz [17] and VCSEL-based optical links with modulation speeds up to 55 Gbit/s have been demonstrated [18], this is approaching fundamental limits. To reach such high and even higher modulation rates over an extended temperature range with sufficient output power suitable for real system environments, radically new design concepts are required, thus opening up an enabling role for T-VCSELs in high-speed data communication.

Similar to conventional VCSELs, T-VCSELs rely on the confinement of the injected carriers to a very small region, typically 10·10 μm² or less. In conventional VCSEL technology this has been achieved in different ways. VCSEL devices typically consist of a cavity region and an amplifying medium sandwiched between two conducting distributed Bragg reflectors (DBRs) through which the drive current is injected. By making most of the topmost DBR non-conducting except for a very small region, the current can be confined to this area. In the early days of VCSEL technology this was usually accomplished using masked proton implantation whereas modern VCSELs use a selective oxidation process. In this scheme, mesas are etched into the VCSEL structure throughout most of the topmost DBR. These mesas are subject to a wet oxidation process where one of layers in the topmost DBR has a composition which corresponds to a significantly higher oxidation rate as compared to the rest of the DBR stack. In this way, a small aperture is formed that confines the current to the central region of the mesa.

The oxidation-confined design has some specific drawbacks. First, the requirement of conducting DBRs also leads to higher optical loss imposed by the doping. Secondly, the oxidation process leads to expansion and stress around of oxidized layer and thereby reliability concerns. Lasers are minority current-based devices and are thereby extremely sensitive to non-radiative recombination through lattice defects. As a consequence, the oxidation layer is usually put some distance apart from the amplifying medium which results in current spreading and loss of efficiency. Thirdly, the selective oxidation is a difficult-to-control process requiring precise control of timing and temperature to monitor the progress of the oxidation front with micrometer precision. This is in contrast to the general low-cost microelectronic-style processing methods that rely on photolithographic techniques to define lateral dimensions. Nonetheless, oxidation-confinement is presently the technology of choice for mass-fabrication of VCSELs with state-of-the-art performances.

In case of T-VCSELs the situation is more complicated. These are three-terminal devices that require the separate contacting of the emitter, base and collector regions, thereby making the contacting through conducting DBRs more difficult. In particular, the thin base region is very difficult to assess through a thick semiconductor DBR structure. Moreover, a proper operation of the device requires well-controlled biasing of these three regions which is difficult to achieve due to lateral voltage drops inside the device. Finally, due to the necessity of a high doping concentration close to the active gain medium, the structure is more sensitive to optical loss which puts additional requirements on an optimized design.

A three-terminal T-VCSEL is disclosed in U.S. Pat. No. 7,693,195 which provides the layer configuration for a functional device and also discusses its operation but omits any details related to the current confinement. Another configuration of a three-terminal T-VCSEL is disclosed in U.S. Patent Application Publication No. 2013/0177036 which makes use of transparent conducting oxide contacts and selective oxidation for the current injection. Three-terminal VCSELs have also been discussed in the open scientific literature. Shi et al. analyzed the performance of oxidation-confined T-VCSELs and demonstrated the enhanced bandwidth as compared to a conventional VCSEL [19] but since this is a purely numerical study any practical difficulties in realizing such a device is not considered, and no experimental result on such a design has so far been demonstrated. Wu, Feng and Holonyak reported the first experimental realization of T-VCSELs in two papers published in the summer of 2012 [20,21]. However, these T-VCSELs had an insufficient current confinement and could only be operated at high threshold and low power. In a subsequent paper [22], the same group introduced a selective oxidation process to lower the threshold current and increase the optical output power but at expense of a complicated and difficult-to-implement processing scheme.

Consequently, there is a need for a revised T-VCSEL design with a current confinement scheme which allows high-performance operation and also corresponds to a robust fabrication procedure. In addition, there is also a need for a viable confinement technology that is not restricted to selective oxidation, which is difficult to implement for other materials systems than AlGaAs/GaAs.

### SUMMARY

There is an object to provide a Transistor Vertical Cavity Surface Emitting Laser T-VCSEL that fulfils at least some of these sought for features. There is also an object to provide a method for producing such a T-VCSEL.

According to a first aspect of the invention there is provided a transistor vertical-cavity surface-emitting laser, T-VCSEL, comprising, a collector comprising a bottom substrate and a base contacting layer,

an emitter and a base arranged between the emitter and the collector, and comprising a light emitting active layer, arranged between layers of a base material, and a collector contacting layer. The emitter comprises a current confining blocking layer that is comprising a first material layer, having a first type of doping and comprising a current confining means and a second material layer having a second type of doping and being provided on the base side of the material layer whereby electrical carriers injected from the emitter flow through the current confining blocking layer confined by the current confining means to arrive at the base to activate the light emitting active layer.

According to a second aspect of the invention there is provided a method for producing T-VCSEL. The method comprises the following steps:

depositing a bottom Distributed Bragg Reflector, bottom DBR, on a substrate

depositing, on the bottom DBR, a p-doped collector layer

depositing a base layer, part of which is n-doped and comprises a light-emitting active layer, on top of the p-doped collector layer

depositing first and second p-doped layers on top of the base layer

etching away a volume through the second p-doped layer, thereby creating a central mesa region

covering the central mesa region with a masking material preventing epitaxial regrowth

growing, by epitaxial regrowth, an n-doped layer on top of the central mesa region covered by the masking material;

removing the masking material from the top of the central mesa region

growing, by epitaxial regrowth, a third p-doped layer over both the central mesa region and the n-doped layer

etching away a volume through the third p-doped layer, the n-doped layer, the first p-doped layer, the base layer and partly through the p-doped collector layer, thus exposing part of the p-doped collector layer

etching away a volume through the third p-doped layer, the n-doped layer, the first p-doped layer and partly through the base layer above the light-emitting active layer, thus exposing part of the base layer;

attaching, an electrical contact on the exposed part of the p-doped collector layer, and an electrical contact on the upper faces of the third p-doped layer;

attaching an electrical contact on the exposed part of the base layer; and

depositing a top distributed Bragg Reflector, top DBR, on the third p-doped layer in such a way that said DBR at least overlies said central mesa region.

The proposed technology thus provides a type of Vertical Cavity Surface Emitting Transistor Laser (T-VCSEL). One particular feature of the T-VCSEL relates to the confinement scheme of the current injection which relies on photolithography and epitaxial regrowth rather than selective oxidation. This yields a T-VCSEL with improved properties compared to prior art. For example, the T-VCSEL according to the invention is easy to manufacture and are more reliable since it avoids the mechanical strain imposed by a selective oxidation step. Furthermore, it has specific performance advantages since the confinement means can be positioned closer to the active region. Also, the T-VCSEL according to the invention is not restricted to AlGaAs/GaAs-based materials but can equally well be applied to other materials systems, which extends the range of possible emission wavelengths, and it does not require electrically conducting top and bottom DBRs. This is an advantage since electrically conducting DBRs must be made out of semiconductor materials which restricts the number of available materials and thereby might lead to non-optimal DBR designs. Also, the requirement on electrically conducting DBRs means that they need to be doped which increases their optical absorption and thereby decreases the efficiency of the device. Finally, the T-VCSEL according to the present invention is easier to manufacture than oxidation-confined T-VCSELs since the base is not covered by a thick semiconductor DBR and can therefore be reached with a shallow and well-controlled etching-step.

### BRIEF DESCRIPTION OF DRAWINGS

FIG. 1 shows a sectional view of an exemplary embodiment of a vertical-cavity surface-emitting transistor laser (T-VCSEL) device according to the invention.

FIG. 2 shows a sectional view of an exemplary embodiment of a T-VCSEL device according to the invention.

FIG. 3 shows a sectional view of another exemplary embodiment of a T-VCSEL device according to the invention.

FIG. 4 schematically illustrates yet another embodiment of a T-VCSEL device according to the invention.

FIG. 5a shows a diagram giving the room-temperature light-current characteristics and optical spectra for a 10·10-μm² device according to the present invention. The two spectra have been vertically displaced for clarity.

FIG. 5B gives a diagram showing I_{C} and V_{BE} as function of I_{B} for different V_{CE} as indicated obtained by using an embodiment of a T-VCSEL according to the invention.

FIG. 5c gives a diagram of a Temperature-dependent operation of a T-VCSEL according to the invention using I_{B} or V_{CE} as control signals.

FIG. 6 illustrates schematically an exemplary embodiment of a T-VCSEL according the present invention.

FIG. 7 illustrates another exemplary embodiment of a T-VCSEL according to the present invention.

FIG. 8 illustrates yet another exemplary embodiment of a T-VCSEL according to the present invention.

FIGS. 9-13 are a sequence illustrating the steps of producing a T-VCSEL according to an embodiment of the invention.

FIGS. 14-17 are a sequence illustrating the steps of producing a T-VCSEL of an alternative embodiment according to the invention.

FIG. 18 shows a top-view of an embodiment of a T-VCSEL according to the invention

FIG. 19 shows possible alternations of the device geometry illustrated in FIG. 18.

The above stated objects together with other objects, advantages and features of the present invention will be more readily understood from the following detailed description of embodiments thereof, when considered in conjunction with the drawings, in which like reference numerals indicate identical structures throughout the several views unless there is explicitly stated otherwise.

### DETAILED DESCRIPTION

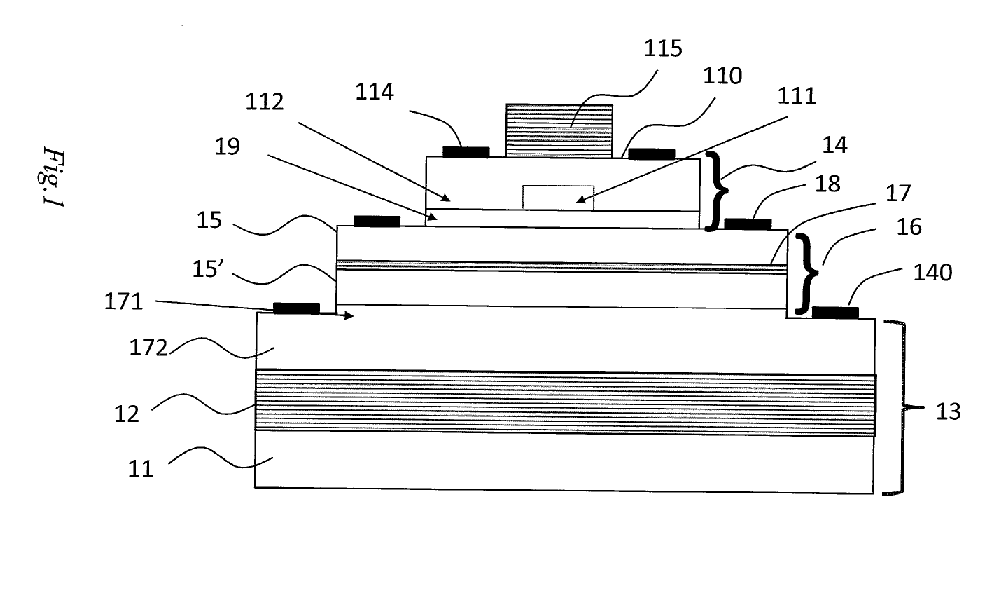

The invention will first be described in conjunction with FIG. 1 which show a sectional view of an exemplary embodiment of the proposed T-VCSEL.

In FIG. 1 there is disclosed a transistor vertical-cavity surface-emitting laser, T-VCSEL, comprising, a collector section 13 comprising a bottom substrate 11 and a base contacting layer 172, defining the collector region, an emitter section 14 and a base section 16, arranged between said emitter section 14 and said collector section 13, and comprising a collector contacting layer 171 and a light emitting active layer 17, arranged between layers 15, 15′ of a base material. The emitter section 14 comprises a current confining blocking layer 110 comprising, a first material layer 112, having a first type of doping and comprising a current confining means 111, 211 and a second material layer 19, defining the emitter region, having a second type of doping and being provided on the base side of the material layer 112, whereby electrical carriers injected from the emitter 14 flow through the current confining blocking layer 110 confined by the current confining means 111 to arrive at the base 16 to thereby activate the light emitting active layer 17.

In FIG. 1 a collector section 13 is thus considered to comprise the layers 11 and 172, the layer 172 is sometimes referred to as the collector region. On the same token, the second material layer 19 of the emitter section is sometimes referred to as the emitter region. The layers 15 and 15′ together with the light emitting active layer 17 of the base section forms part of what is sometimes called an etched mesa structure. The base material and the type of doping of the layers 15 and 15′ might differ.

In an exemplary embodiment of a T-VCSEL according to above the first material layer 112 and the second material layer 19 are layers of a semi-conducting material.

In a particular embodiment of a T-VCSEL according to the above given embodiments will the first material layer 112 comprise an n-doped material layer and the second material layer 19 will comprise a p-doped material layer.

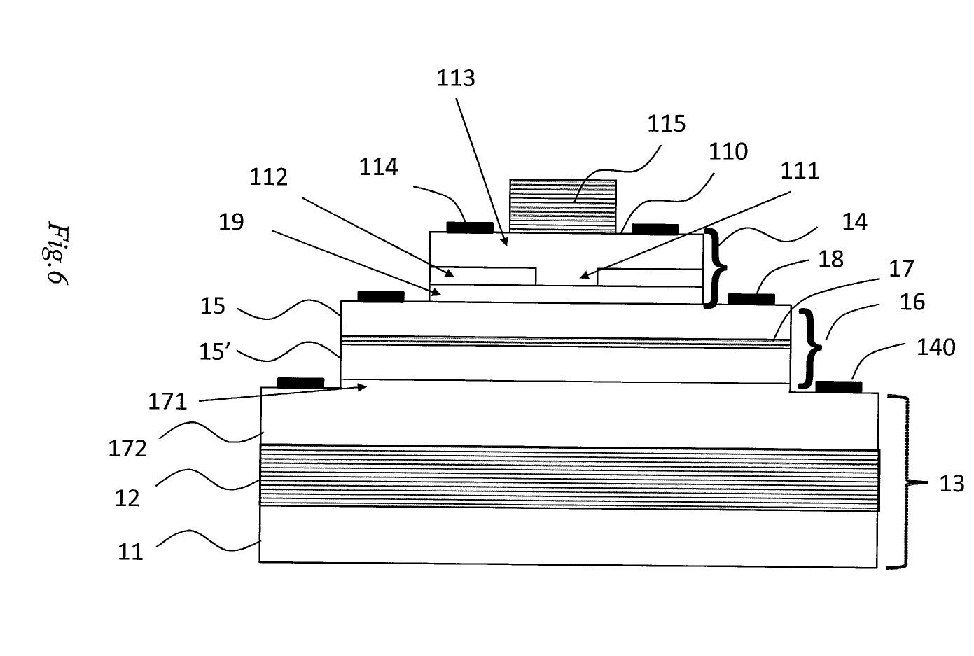

With reference to FIG. 6, there is shown a possible embodiment of a T-VCSEL according to earlier described embodiments, wherein the current confining blocking layer 110 further comprises a third material layer 113 arranged on the first material layer 112 on the side farthest from the base 16. The third material layer 113 is preferably provided with the same doping type as the second material layer 19.

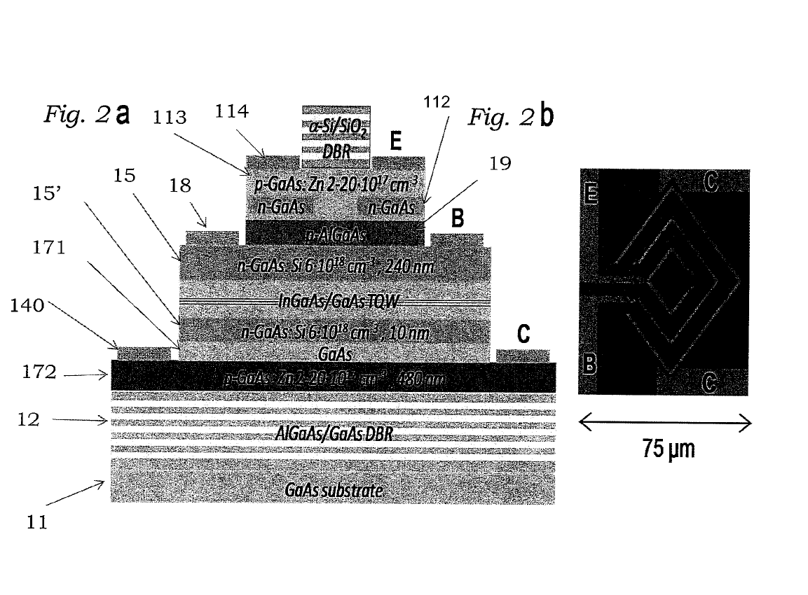

In an exemplary version of this embodiment of a T-VCSEL, the current confining means 111 will comprise a square-shaped section 111 extending through the first material layer 112, and containing at least part of the third material layer 113 to thereby confine carriers injected from the emitter to the base section to flow in section 111. This embodiment of the current confining means is schematically disclosed in FIGS. 2 and 6.

In a possible version of a T-VCSEL comprising a third material layer, is the material of the first material layer 112 GaAs, the material of the second material layer 19 AlGaAs and the material of the third material layer 113 GaAs. This is schematically shown in FIG. 2.

FIG. 2 schematically illustrates an exemplary version of a base section 16 of the earlier described embodiments of a T-VCSEL. Here the light emitting active layer 17 in the base 16 comprises a multilayered InGaAs/GaAs triple quantum well active layer, having alternating InGaAs layers and GaAs layers, arranged between layers 15, 15′ of a base material that is an n-doped GaAs material and provided on top of the collector contacting layer 171.

Still another possible embodiment of a T-VCSEL is shown in FIG. 2, here there is disclosed that the base contacting layer 172 of the collector section 13 is a p-doped GaAs layer and the collector contacting layer 171 of the base section 16 is a GaAs layer.

In all the earlier disclosed embodiments of a T-VCSEL the second material layer 19 can be provided with a reduced or non-uniform doping concentration that is higher closer to the base 16. In this way the lateral resistance of the material layer 19 will be high, thus leading to a low lateral current spreading while the vertical current blocking properties of the current confining layer are preserved.

The invention as described above details a vertical-cavity surface-emitting transistor laser (T-VCSEL) based on a pnp-type blocking layer for current confinement. Beyond this, the invention also embodies variations of the invention where the heterojunction bipolar transistor has an n-p-n doping sequence for the emitter-base-collector regions, respectively, and thereby the blocking layer consequently has an npn configuration. In this case, the corresponding layer and device structure remains the same as the device shown in FIG. 2 with the exception that all n-doped layers should be p-doped, and vice versa. A description of a corresponding diode-type for conventional VCSEL is found in R. M. Marcks von Würtemberg et al, IET Optoelectronics, 3 (2), 112 (2009).

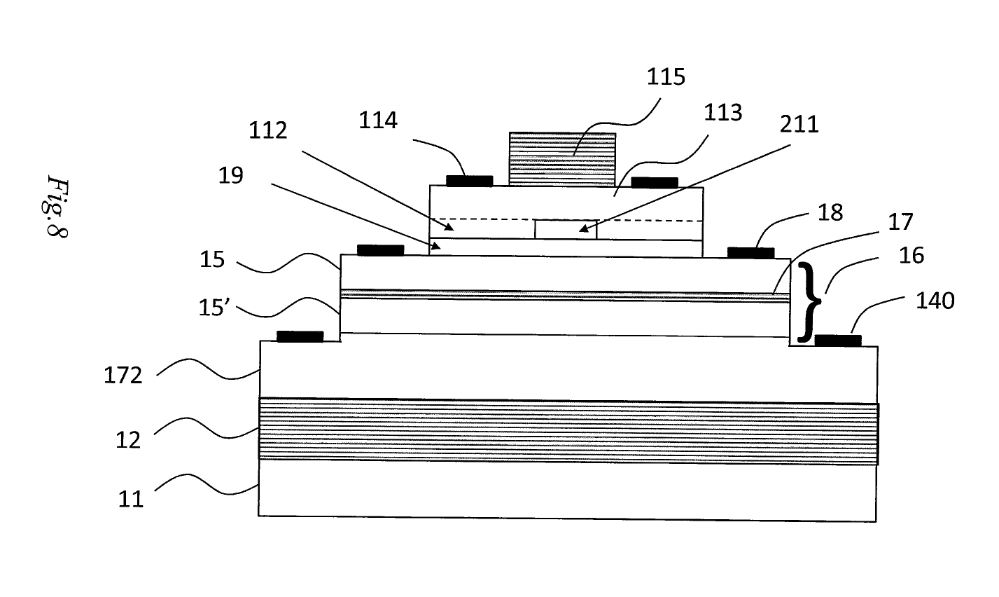

In other words, another possible version of a T-VCSEL will be described in what follows, Thus, in FIG. 8, there is disclosed a T-VCSEL that is provided with current confining means 211 that comprises an n⁺p⁺ tunnel junction 211 buried in the first material layer 112 and connecting the first material layer 112 to the second material layer 19 thus providing carrier injection from said emitter section 14 to said base section 16.

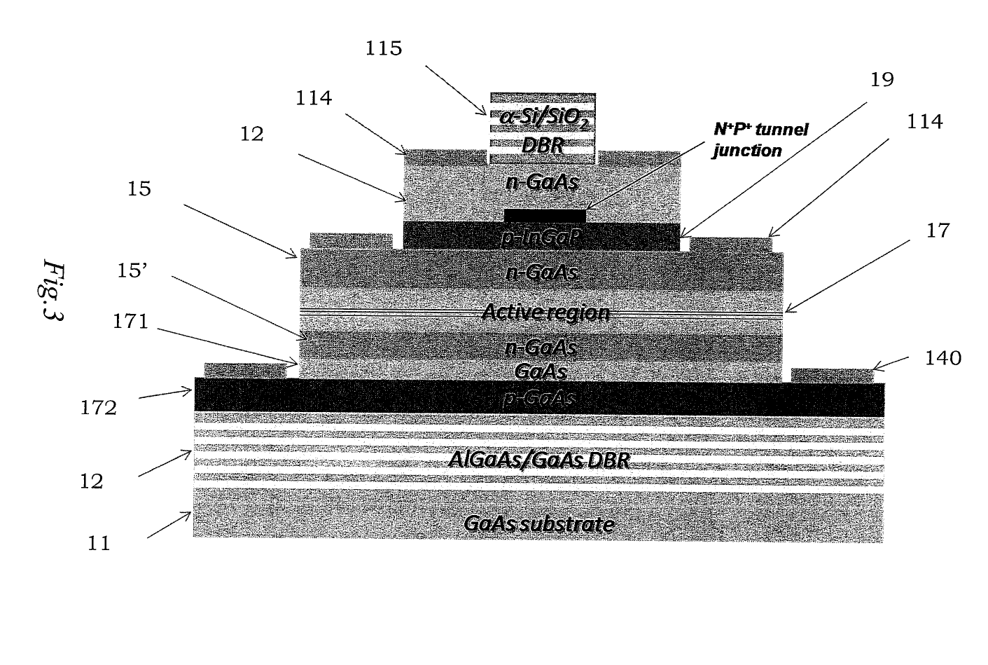

In FIG. 3 is illustrated a version of the T-VCSEL shown in FIG. 8, where the first material layer 112 comprises an n-doped layer and the second material layer 19 comprises a p-doped layer. The materials of this T-VCSEL might have first material layer 112 that is a GaAs-layer and a second material layer 19 that is an InGaP-layer. This is explicitly shown in FIG. 3.

In a T-VCSEL schematically shown in FIG. 8 the light emitting active layer 17 in the base section 16 might comprise an InGaAs/GaAs triple quantum well active layer, with alternating InGaAs layers and GaAs layers embedded within layers 15, 15′ of a base material of an n-doped GaAs material, and provided on top of a collector contacting layer 171.

In an exemplary embodiment of a T-VCSEL the base contacting layer 172 of the collector section 13 is a p-doped GaAs layer and the collector contacting layer 171 of the base section 16 is a GaAs layer.

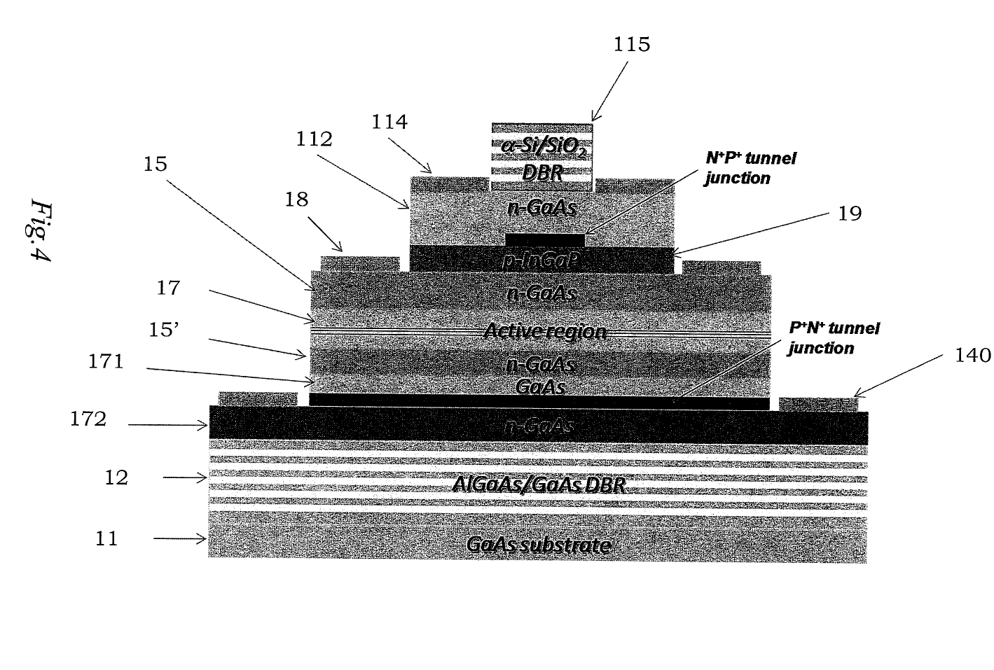

A version of the above described T-VCSEL is schematically shown in FIG. 4, here the T-VCSEL further comprises a p⁺n⁺ tunnel junction arranged between the collector contacting layer 171 and the base contacting layer 172.

In still another version of a T-VCSEL is the collector contacting layer 171 a GaAs layer and said base contacting region 172 is an n-doped GaAs layer.

In all of the earlier disclosed embodiments of a T-VCSEL the second material layer 19 can be provided with a reduced or non-uniform doping concentration that is higher closer to the base section 16. In this way the lateral resistance of the material layer 19 will be high, thus leading to a low lateral current spreading while the vertical current blocking properties of the current confining layer are preserved.

Any of the earlier described embodiments of a T-VCSEL can be provided with a collector section 13 that comprises a multi-layered distributed Bragg reflector, DBR, 12 provided between the bottom substrate 11 and the base contacting layer 172. This distributed Bragg reflector 12 might comprise a multi-layered structure with alternating AlGaAs layers and GaAs layers. Alternatives of a T-VCSEL with such distributed Bragg reflectors are shown in FIGS. 2-4.

A T-VCSEL according to earlier described embodiments might also comprise an emitter section that comprises a multi-layered distributed Bragg Reflector, DBR, 115 arranged on the current confining blocking layer 110 on the side farthest from the base section 16. This is shown in, for example, FIGS. 1 and 8.

The above described multi-layered DBR might comprise a-Si layers alternated with SiO₂ layers.

In all of the earlier described embodiments the bottom substrate 11 of the collector section 13 of the T-VCSEL might comprises a GaAs substrate.

It is also possible to provide a variation of earlier described embodiments of a T-VCSEL where the type of doping of the various layers has been exchanged, or substituted for each other. In other words a T-VCSEL wherein p-doped materials are exchanged with corresponding n-doped materials and wherein said n-doped materials are exchanged with corresponding p-doped materials.

Moreover, as will be described more detailed below, any of the earlier described embodiments of a T-VCSEL might further comprise a collector contact 114, corresponding to a first terminal arranged on the emitter 14, a base contact 18, corresponding to a second terminal, arranged on the base 16 and a collector contact 140, corresponding to a third terminal, arranged on the collector 13.

The collector 13 of the earlier described embodiments of a T-VCSEL might modulation doped for efficient collector current injection while minimizing the optical absorption.

The earlier described embodiments of a T-VCSEL might also be provided with a light-emitting active layer 17 that consists of quantum-dots, quantum dashes or any other active layer material suitable for semiconductor lasers.

The earlier described embodiments of a T-VCSEL might also be provided with a third material layer 113 that is modulation doped to obtain efficient emitter-current injection and minimize optical losses.

A version of the earlier described embodiments of a T-VCSEL could also have the indicated doping types reversed, for example, an n-type collector section 13 instead of a p-type; a p-type base section 16 instead of an n-type, an n-type emitter section 19 instead of a p-type; instead of a p-type third material layer an n-type third material layer 113, and finally a p-type first material layer 112.

The earlier described embodiments of a T-VCSEL could preferably have a second material layer 19 that consists of a semiconductor compound with similar or larger band-gap as compared to the base region of the base section 16 and collector region of the collector section 13.

A version of the earlier described embodiments of a T-VCSEL could also be provided where the combined thicknesses of the layers 19, 111 and 113, which might be semi-conducting, are larger than the combined thickness of the possibly semiconducting layers 19, 110 and 113 at the peripheral region of the T-VCSEL thereby providing a lateral variation in the cavity thickness which will confine the laser light to the central region.

In a particular embodiment of a T-VCSEL according to the earlier described embodiments, the surface of the third material layer 113 could have a convex lens-like shape. This particular shape might spontaneously form during epitaxial regrowth of the third material layer 113.

To facilitate a deeper understanding of a T-VCSEL according to the invention in what follows there will be provided descriptions regarding the functionality of the various embodiments as well as descriptions for manufacturing procedures for obtaining particular embodiments of a T-VCSEL according to the invention. These descriptions are merely intended to provide a, hopefully, clear description of the invention and anything explicitly stated in the examples should not be construed as limiting features.

Seen in FIG. 6 is the bottom substrate 11, the bottom DBR 12, the collector section 13, the base section 16, the light-emitting active layer 17, the second material layer 19 and the top DBR 115. Furthermore, the collector, base and emitter contacts are labelled 140, 18 and 114, respectively. After growth of the second material layer 19, defining the emitter region, and, to be specific, a p-doped layer, part of which is the square-shaped section 111, the peripheral region of that layer is etched away while the central part 111 is protected by an appropriate mask layer, e.g. SiO₂ or Si₃N₄, thus forming a mesa structure. In this particular version the first material layer 112 is an n-type blocking layer 112 that is added using epitaxial regrowth while growth on top of the mesa is prevented by the mask layer. Finally, the mask layer is removed and, in this particular embodiment, the p-doped third material layer 113 is added in a second regrowth step, covering both the first material layers 112 and the square-shaped section 111. In this structure, when a voltage is applied to the emitter contact 114 and the base contact 18, the np-junction formed between the layers 112 and 19 will be reverse-biased and will therefore not conduct any current. The current will instead flow laterally through the second epitaxial regrowth layer 113 and then vertically through the unipolar junction between layers 113 and 111 and the forward-biased pn-junction between the second material layer 19 and the base section 16 where light will be generated at the central region of the light-emitting active layer 17.

To laterally confine the laser light mode to the central region of the device so that it overlaps with the gain in the light-emitting active layer, the thickness of the first regrown layer 112 is in a particular embodiment smaller than the mesa etch depth that defines the square-shaped section, or the central region, 111. In this way a structure is created with laterally varying optical properties that laterally confine the laser light to the region 111.

If the thickness of the first regrown layer 112 is made smaller than the mesa etch depth, this has additional consequences. During growth of the regrown layer 113, a crystallographic plane of high lateral growth rate will spontaneously be formed at the edge of the central region 111. As the growth of the layer 113 proceeds, this moves the step in the total cavity thickness (i.e. combined thicknesses between the bottom DBR 11 and top DBR 115) outwards, i.e. away from the central region 111. Such a change in lateral position of the step has useful properties. The lateral size of the laser light modes that are confined by the step will increase as the step moves outwards. The gain in the light-emitting active layer will, however, remain in the central region below the square-shaped section, or the central region, 111. This means that the optical gain will overlap more with, and thereby provide more modal gain, to laser light modes that have higher optical intensity in the central region, e.g. the fundamental laser light mode. This can be used to force the structure to emit light in the fundamental laser light mode only, which is desirable in many applications.

Another feature of the invention is that as the step in total cavity thickness moves away from the central mesa region 111 during growth of the regrown third material layer 113, the surface of the regrown third material layer 113 in the central region confined by the step in total cavity thickness spontaneously becomes curved with a convex lens-like shape. Such a shape is desirable as it provides optical confinement of the laser light without the diffraction losses induced by the step in the total cavity thickness mentioned above. The spontaneous formation of such a curved shape is a big advantage as deliberate formation of such a shape, e.g. by etching, is difficult, especially if a high degree of uniformity within a wafer or between wafers is needed.

The radius of the regrown third material layer 113 will determine the area to which the laser light will be confined. A smaller radius of curvature will confine the laser light to a smaller area while a larger radius of curvature will confine the laser light to a larger area. The radius of curvature can be tailored by varying the difference between the mesa etch depth and the thickness of the regrown third material layer 113. A smaller difference will give a larger radius of curvature while a larger difference will give a smaller radius of curvature. In addition, the radius of curvature can be controlled by the growth parameters, e.g. the growth temperature or growth rate, which controls lateral diffusion of adatoms and thereby the lateral-to-vertical growth rate ratio.

In another embodiment of the invention, lateral current spreading in the peripheral part of the second material layer 19, or emitter region 19, is reduced by a reduced or non-uniform doping of this layer. If the peripheral region of the layer 19 in the blocking layer 110 is highly conductive, the injected current will spread laterally before reaching the light-emitting active layer 17 which leads to a reduced efficiency of the laser. This can be avoided from a reduced doping concentration in the layer 19 so that this layer is almost fully depleted (and thus non-conducting) by the reverse-bias over the np-junction between layer 110 and the peripheral part of layer 19. However, this may lead to problems if the T-VCSEL is used in application where the bias between the emitter, base and collector contacts varies in time, which is e.g. the case for directly modulated light sources in fiber-optical communication systems. In such a case, the depletion layer, and thereby the conductivity of the peripheral layer 19 will vary with the applied voltage. As a consequence, the current spreading and thereby the efficiency of the laser will depend on the drive current of the laser, which is undesirable since it e.g. will make the design of the drive circuitry more difficult.

The above described effect of varying efficiency with applied voltage can be reduced if the doping concentration in the layer 19 has a non-uniform doping concentration that is lower towards the top of this layer and higher towards the bottom of the layer, i.e., towards the light-emitting active layer 17. In this configuration, the upper, peripheral part of layer 19 of the blocking layer 110 will always be fully depleted regardless of the applied bias (as long as the polarity of the bias is such that the emitter-base junction, i.e. the junction between the layer 19 and the base section 16, is forward-biased), while the lower part only will be depleted to a small extent that does not vary much with the applied bias (at least under normal drive conditions). The lower part of layer 19 with high doping concentration can therefore made thin and will consequently have a relatively high lateral resistance, thus limiting the current spreading to such an extent that the efficiency of the laser is reduced.

An additional benefit of keeping the highly doped part of layer 19 thin is that this can be used to reduce the optical absorption in that layer. The optical absorption in semiconductor layers usually increases with doping, especially p-type doping, and decreases the efficiency of the laser. However, the optical absorption in a laser structure can be reduced if the doped layer is positioned in a node of the standing wave optical field, but the thicker this layer is, the more it will penetrate regions where the standing wave optical field intensity in the laser is larger and thereby affect the efficiency of the laser. Consequently, the efficiency of the laser can be increased from a non-uniform doping concentration of layer 19 if the highly doped part of this layer is positioned close to a node of the standing wave optical field.

With reference to the T-VCSEL of FIGS. 2a and 2b, in what follows we will provide a description of an embodiment of a T-VCSEL according to the invention that demonstrate the first room-temperature operation of a transistor vertical-cavity surface-emitting laser (T-VCSEL). Fabricated using an epitaxial regrowth process, the T-VCSEL is electrically a Pnp-type bipolar junction transistor and consists of an undoped AlGaAs/GaAs bottom DBR, an InGaAs triple-quantum-well (TQW) active layer, an Si/SiO₂ dielectric top DBR, and an intracavity contacting scheme with three electrical terminals. The output power is controlled by the base current in combination with the emitter-collector voltage, showing a voltage-controlled operation mode. A low threshold base-current of 0.8 mA and an output power of 1.8 mW have been obtained at room temperature. Continuous-wave operation were performed up to 50° C.

FIG. 2a discloses a GaAs-based Pnp-type 980-nm T-VCSEL. FIG. 2a gives a schematic cross-section of the T-VCSEL. The emitter and sub-collector regions are modulation doped for minimized optical loss. The emitter (E), base (B) and collector (C) contacts are indicated. FIG. 2b gives a top-view optical micrograph of a fabricated T-VCSEL.

For this particular T-VCSEL continuous-wave operation is demonstrated up to 50° C. with a room-temperature (RT) output power of 1.8 mW for a 10·10-μm² device, controlled by the base current in combination with the collector-emitter voltage. To the best of the inventors knowledge, this is the first demonstration of the room-temperature operation of a T-VCSEL.

Device design of the T-VCSEL and fabrication of the same: A schematic drawing of such a T-VCSEL is shown in FIG. 2a. First, the bottom 35.5 pair Al_{0.88}Ga_{0.12}As/GaAs Distributed Bragg Reflector (DBR), the collector, base and emitter regions are grown using metal-organic vapour phase epitaxy. Embedded in the base region is an InGaAs/GaAs triple quantum-well (TQW) active layer with photoluminescence wavelength of 965 nm. A square-shaped mesa is etched through the emitter, thereby defining the active region, and an n-type GaAs layer is regrown around the mesa for electrical confinement. Then the whole structure is overgrown by a p-type GaAs layer that completes the emitter region and the five-lambda thick cavity. Larger mesas are etched to access the n-type base region and the p-type sub-collector. Finally, a high contrast, low loss dielectric DBR made out of three pairs of alternating layers of SiO₂ and α-Si is deposited on the cavity region. The laser structure is similar to our previous 1300-nm VCSEL design with the details given in Ref. 9.

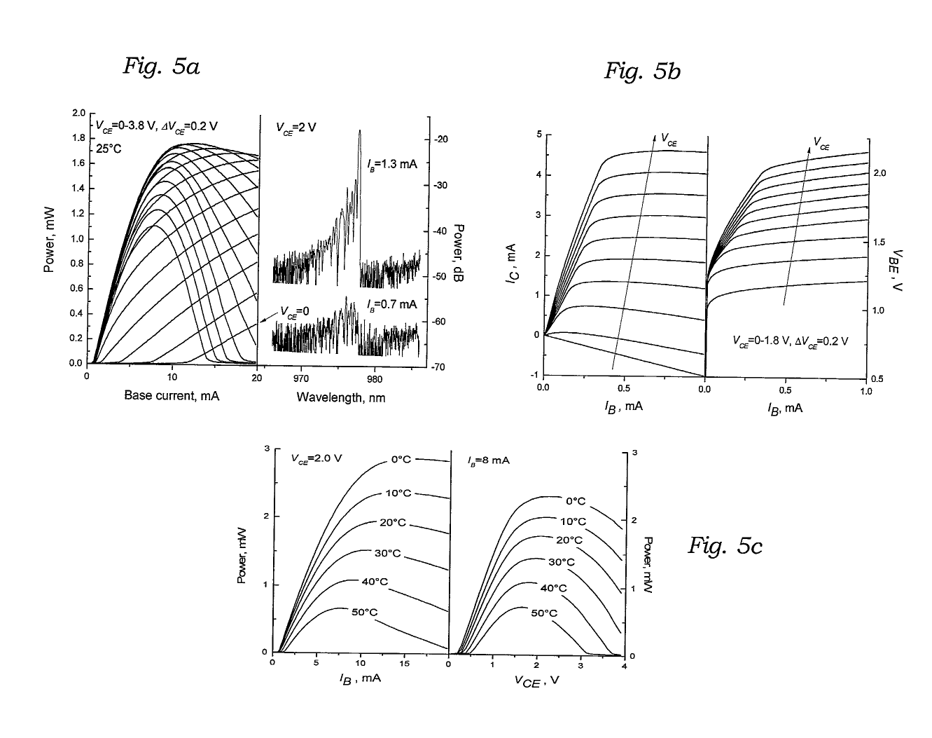

FIGS. 5a-5c illustrates some measured characteristics for a particular type of T-VCSEL. The particular type of T-VCSEL is schematically given in FIG. 2. FIG. 5a shows the measured optical output power (Pₒᵤₜ) as function of the base current (I_{B}) for different collector-emitter voltages (V_{CE}). For low values of V_{CE}, Pₒᵤₜ and the differential slope efficiency increases while the threshold current decreases with increasing V_{CE}, reflecting the gradually increased reverse-bias voltage on the base-collector (BC) junction. For higher values of V_{CE}, Pₒᵤₜ saturates and starts to decrease due to thermal roll-over caused by self-heating. The threshold base current for V_{CE}>1 V is around 0.8 mA. The optical spectra are taken just below and slightly above the threshold current. The measured linewidth of the leading mode is ˜0.1 nm, limited by the resolution of the optical spectrum analyzer.

That is, FIG. 5a disclosed room-temperature light-current characteristics and optical spectra for a 10·10-μm² device. In the figure the two spectra have been vertically displaced for clarity

FIG. 5b shows I_{C} and V_{BE} as function of I_{B} for different values of V_{CE}. For V_{CE}=0, I_{C} is negative throughout the range of I_{B} since both junctions (EB and CB) are forward biased with corresponding hole injection into the base. For V_{CE}>0, I_{C} initially increases with increasing I_{B} but then saturates and starts to gradually decrease. Considering the detailed geometry and the biasing configuration of the device, this behaviour is attributed to a gradual turn-on of the CB junction, starting from the edge close to the collector contact and progressing towards the centre region with increasing I_{B}. The current injected close to the collector contact will not contribute to the lasing modes since it is only pumping the peripheral part of the active region outside the optical cavity. Beyond the kinks in the I_{C}-versus-I_{B} characteristics, I_{C} is composed of two parts; a reverse current at the central part of the device and a forward current in the peripheral region that adds to the rapidly increasing I_{B}, eventually summing up to I_{C}<0. In the central region, holes injected from the emitter and electrons diffusing from the base contact provide the optical gain.

FIG. 5c shows temperature-dependent current as well as voltage-controlled operation of the T-VCSEL. The high-temperature performance can even further be improved by increasing the spectral offset between the active layer gain maximum (λ_{g}) and the cavity resonance (λ_{cav}). The minimum in threshold current occurs at around 10° C., corresponding to a slight negative tuning at RT (λ_{g}−λ_{cav}≈−15 nm). For the voltage-controlled operation, I_{B} is set to 8 mA while Pₒᵤₜ versus V_{CE} are recorded at different temperatures. Similar to the current-controlled operation, a pronounced lasing threshold is observed and Pₒᵤₜ is limited by self-heating and thermal roll-over at high voltages. This voltage-controlled operation is unique to transistor lasers and may find important applications [19].

In another embodiment of the invention, the current confinement (carrier injection from the emitter to the base) is arranged by the insertion of a reverse-biased p⁺n⁺ tunnel diode, as e.g. described in the case of conventional diode vertical-cavity surface-emitting lasers (diode VCSELs); see, e.g., Y. Onishi et al., IEEE J. Sel. Top. Quantum Electron, 15 (3), 838 (2009). FIG. 3 outlines this configuration in case of the T-VCSEL considered in the present invention.

FIG. 3 discloses schematically a PNP-type T-VCSEL based on a buried tunnel junction for current injection. As compared to the pnp-type blocking layer configuration this design has the advantage of being limited to one regrowth step. Also, it takes advantage of a reduced optical absorption and higher electron mobility in the emitter region.

In yet another variant of the invention, tunnel junctions are used both to confine and inject carriers into the base from the emitter and also to extract the injected carriers from the base to the collector. The advantage of this approach is that the structure is almost exclusively n-doped, leading to high carrier mobility and suppressed free-carrier absorption. FIG. 2 shows a schematic cross-section of such a T-VCSEL. That is a PNP-type T-VCSEL based on buried tunnel junctions for current injection as well as base collector carrier extraction is shown. Also this design has the advantage of being limited to one regrowth step.

Modulation doping in grown semiconductor layers are used to minimize optical absorption and/or improve the carrier distribution. Highly doped regions are positioned at a node of the standing wave optical field of the lasing light, and vertically varying doping levels are used to control the lateral resistance and thereby the current spreading.

That is, in another embodiment of the invention, the current constricting structure makes use of a highly conductive reverse-biased buried tunnel junction 211 positioned in the central region of the device, while the current is blocked in the peripheral region due to a reverse-biased pn-junction. A tunnel junction might consist of a highly doped p⁺n⁺-diode and has the very interesting property that the conduction through it relies on direct electron tunnelling form the valance band in the p-doped side to the conduction band in the n-doped side. This is made possible by the degenerate doping concentrations of the semiconductor on both sides of the junction so that filled electron states in the valance band on the p-side overlap with empty electron states on the n-side. An increased reverse bias will increase this overlap and the current will thus increase rapidly with increasing reverse bias. FIG. 8 shows such a buried tunnel junction T-VCSEL. Here, layer 19 denotes a p-doped second material layer, while the third material layer 113 as well as the base 16 is n-doped. The tunnel junction consist of a (from top to bottom) n⁺p⁺-bilayer. A positive voltage on the emitter contact 114 with respect to the base contact 18 and collector contact 14 will thereby result in a reverse bias over the tunnel junction so that holes are injected into the central region of the emitter and then further over the forward biased emitter-base pn-junction, while hole injection is effectively blocked in the peripheral region outside the tunnel junction due to the reverse-biased np-junction. There are three main advantages with this device configuration as compared to the one relying on a peripheral pnp-type blocking layer described above. First, it is somewhat simpler to fabricate since it only involves one regrowth step. Secondly, the tunnel junction can be made very thin and thus makes it possible to fabricate a very shallow mesa structure and thereby allows an increased flexibility in the device design, e.g. in order to engineer the optical mode. Thirdly, the third material layer 113 has n-type rather than p-type doping (for a pnp-type T-VCSEL) which corresponds to lower optical absorption and thereby a higher efficiency of the laser. A drawback is that it is less suitable for a npn-type T-VCSEL since it would require p-type doping of the otherwise n-type third material layer 113.

In yet another embodiment of the invention, also the base-collector junction consists of n⁺p⁺-bilayer, thus forming a forward-biased tunnel junction. This configuration has the advantage that almost the entire device can be made n-type (for a pnp-type T-VCSEL) except for the p+-layer in the tunnel junction itself and the thin second material layer 19. Also, the doping and band alignment of the tunnel junction will set a limit for the maximum applied voltage across this junction since an increasing forward bias eventually will decrease the overlap between occupied electron states in the conduction band on the n-side and un-occupied electron states in the valence band on the p-side. Also this device configuration is less suitable for a npn-type T-VCSEL since that would result in an almost completely p-type device and thereby an overall high optical absorption.

A specific advantage of the embodiments of the present invention is that, in contrast to oxidation-confined T-VCSELs in the prior art which preferably are made out of the AlGaAs/GaAs materials system since selective oxidation is difficult in other materials systems, lend itself equally well to alternative materials systems such as GaAs, InP, GaN, GaSb, etc, and thereby can be used to fabricate emitters for a wide wavelength range, including but not limited to 850, 980, 1310, 1490 and 1550 nm.

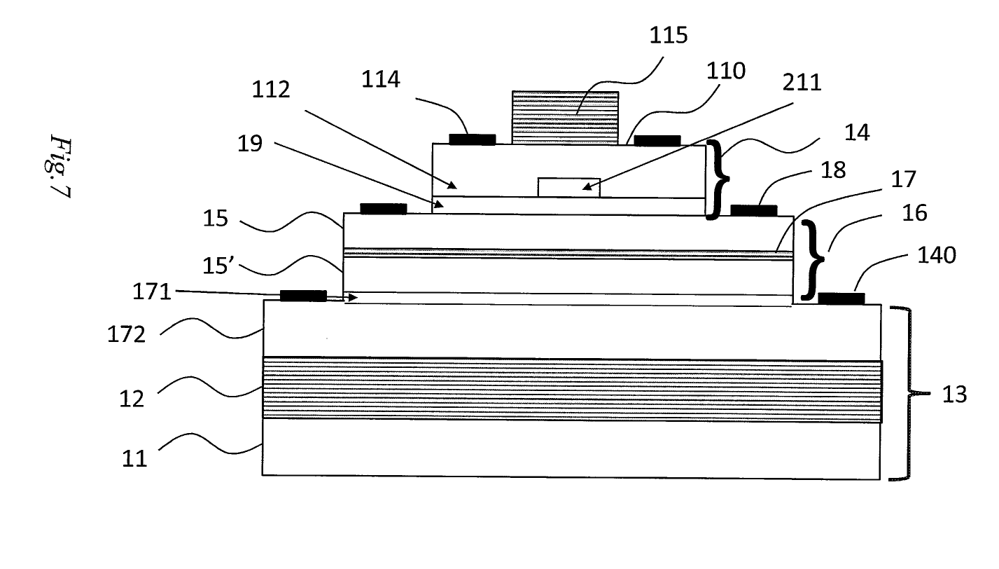

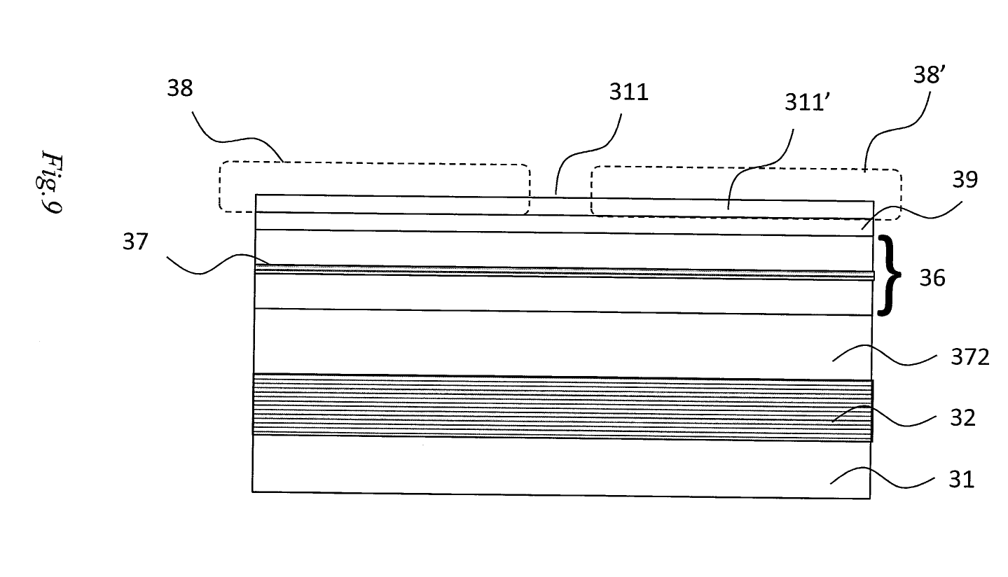

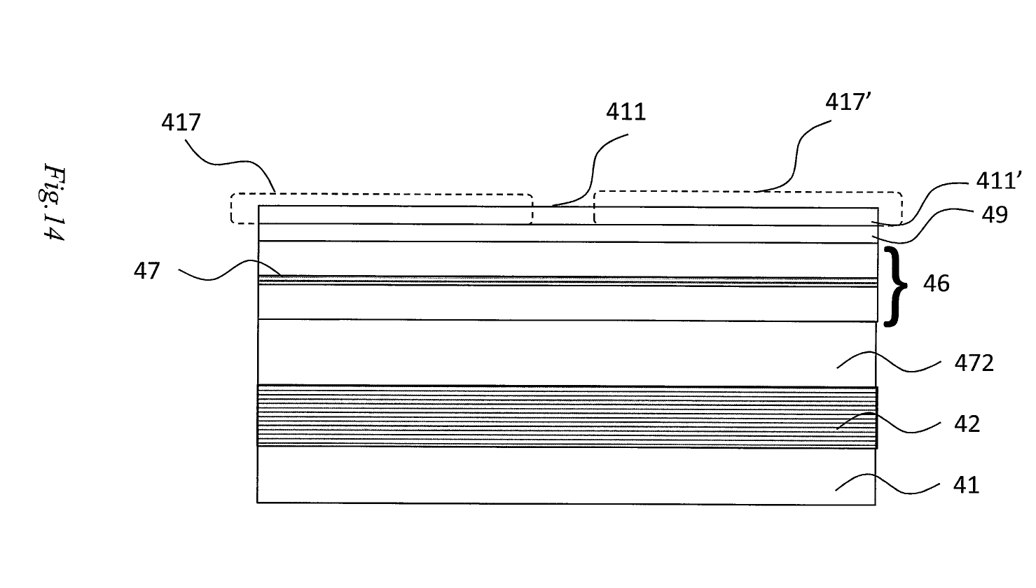

The fabrication procedure of the T-VCSEL according to a first embodiment of the invention will now be described with reference to FIGS. 9-13. The reference numerals in these figures have been slightly changed from earlier drawings in so far as the reference numerals in FIGS. 9-13 have been given the first digit 3 instead of 1 as in earlier the FIGS. 1-8, and the reference numerals in FIGS. 14-17 have instead been given the first digit 4 instead of 3. To clarify, a structure that were given the reference numeral 110 in drawings 1-9 will correspond to a structure 310 in FIGS. 9-13 and to a structure 410 in FIGS. 14-17, etc. Moreover intermediate steps in the methods described below provides mesa regions corresponding to specific parts in the earlier described collector section, emitter section and base section, respectively. The term mesa region is used since it is the usual term used in the fabrication process of multi-layered structures and it will therefore be easier for a person skilled in the art to understand the fabrication method. With a mesa region is in general meant a multi-layered section where parts of the volume of the layers have been removed, i.e. through etching. After the etching has been performed on the multi-layer section, removing certain parts of the volume, the remaining volume is referred to as a mesa region or alternatively as a mesa.

With reference to FIG. 9, the method for producing a T-VCSEL begins by depositing a bottom DBR 32 on a bottom substrate 31. After that part of the cavity consisting of layers 372, 36 and 39 (also corresponding to the collectors base contacting layer 372, the base section 36, or emitter region 39, including the light-emitting active layer 37 of the base) is provided. After that a layer 310 is deposited. Thereafter a mesa 311 is formed by etching away the volume corresponding to area 38 and 38′. It should be understood that, in the description in the embodiments according to the invention, when shown an area in the cross-section this normally corresponds to a volume.

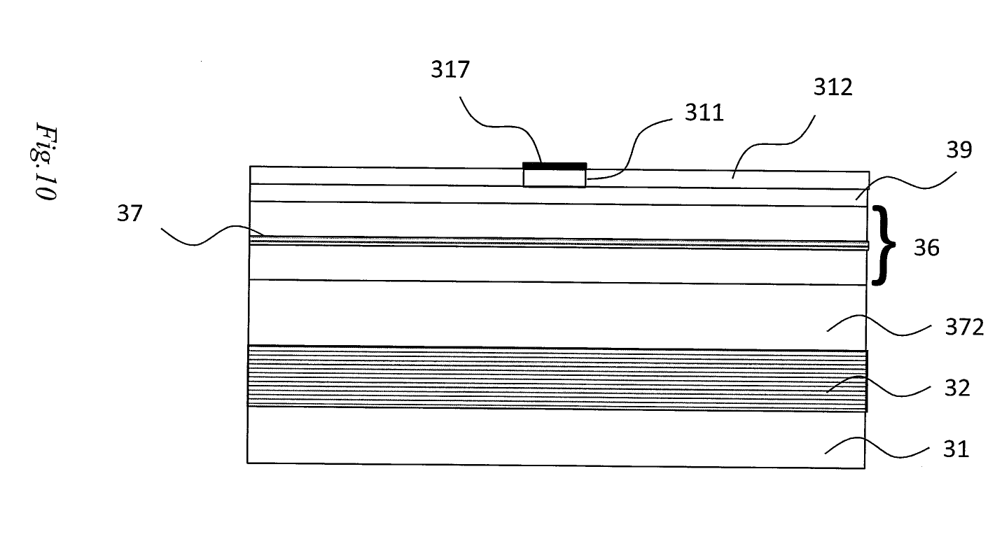

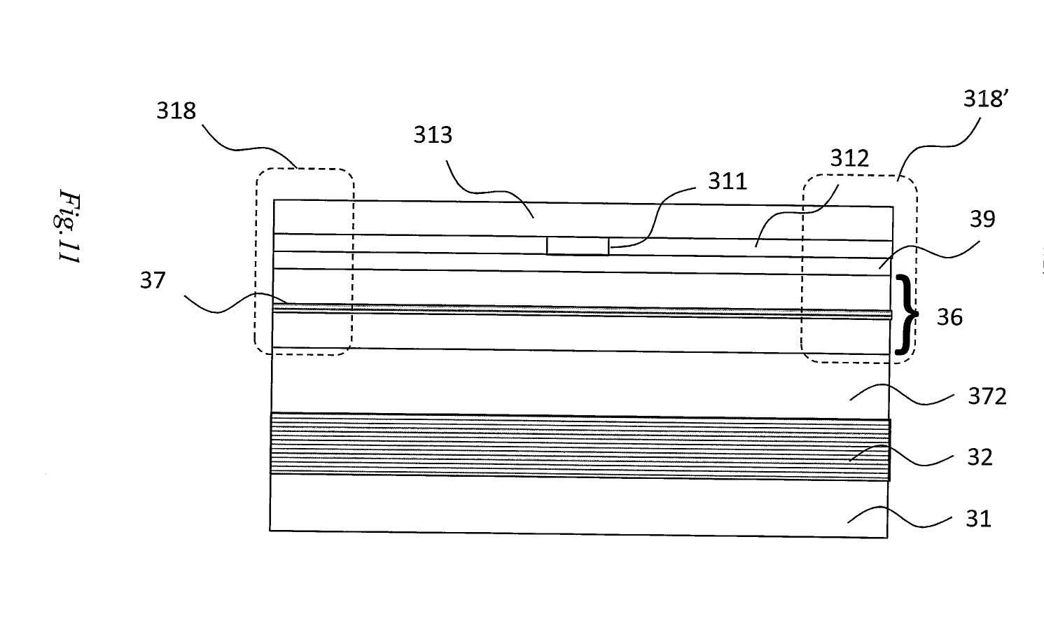

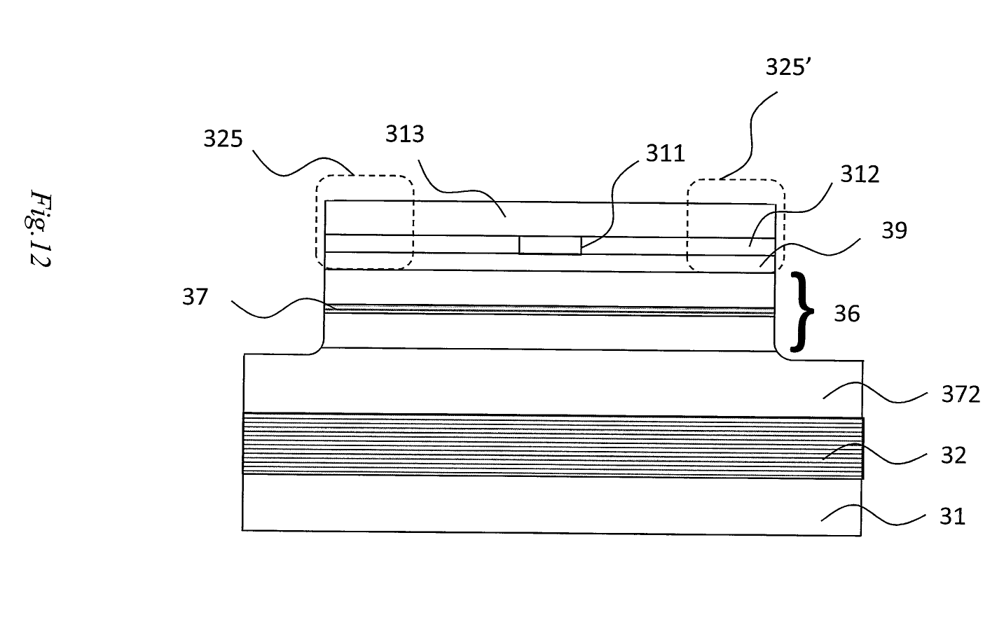

The current constricting layer 312 is then deposited by area-selective epitaxial regrowth while the top of the current confining blocking layer 311 is covered by a masking material 317 that prevents epitaxial growth from occurring there, this is schematically illustrated in FIG. 10. This is followed by the removal of the masking material 317 on top of the current confining block layer 310 and the subsequent epitaxial regrowth of the remaining part of the cavity over both the peripheral area of layer 312 and the central mesa region 311. This regrowth layer corresponds to layer 313 in FIG. 11. To access the base and collector regions, volumes 318 and 318′, shown in FIG. 11, and volumes 325 and 325′, shown in FIG. 12, are removed by means of etching. This etching exposes part of the layers 36 and 372, and a base contact 38 and a collector contact 340 are placed on the exposed parts of the layers 36 and 372, respectively. An emitter contact 314 is provided on layer 313.

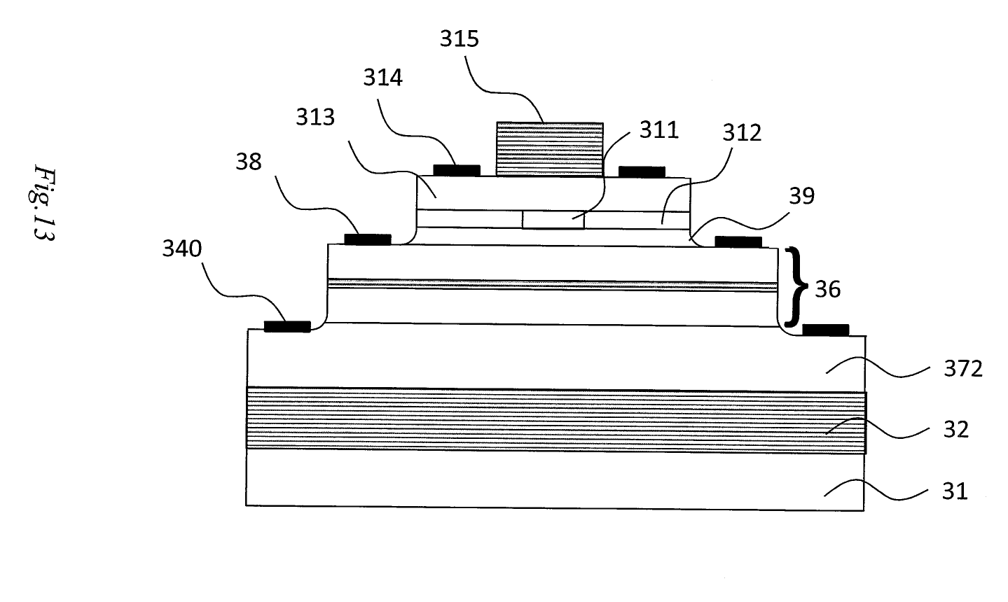

Thereafter, the top DBR 315 is deposited on the regrowth third material layer 313, in such a way that it is overlying the central mesa region 311. The DBR 315 could also be deposited so that it also at least partly overlies the peripheral regions of layer 313 and layer 312. The end product is schematically illustrated in FIG. 13

In other words, there is provided a method for producing a T-VCSEL, the method comprises the following steps:

depositing Si a bottom Distributed Bragg Reflector, bottom DBR, 32, on a substrate 31;

depositing S2, on said bottom DBR 32, a p-doped collector layer 372;

depositing S3 a base layer 36, part of which is n-doped and comprises a light-emitting active layer 37, on top of said p-doped collector layer 372;

depositing S4 first 39 and second 311′ p-doped layers on top of said base layer 36;

etching S5 away a volume 38, 38′ through said second p-doped layer 311′, thereby creating a central mesa region 311;

covering S6 said central mesa region 311 with a masking material preventing epitaxial regrowth;

growing S7, by epitaxial regrowth, an n-doped layer 312 on top of the central mesa region 311 covered by the masking material;

removing S8 the masking material from the top of the central mesa region 311;

growing S9, by epitaxial regrowth, a third p-doped layer 313 over both the central mesa region 311 and the n-doped layer 312;

etching S10 away a volume 318, 318′ through the third p-doped layer 313, the n-doped layer 312, the first p-doped layer 39, the base layer 36 and partly through the p-doped collector layer 372, thus exposing part of the p-doped collector layer 372;

etching S11 away a volume 325, 325′ through the third p-doped layer 313, the n-doped layer 312, the first p-doped layer 39 and partly through the base layer 36 above the light-emitting active layer 37, thus exposing part of the base layer 36;

attaching S12, an electrical contact 340 on the exposed part of the p-doped collector layer 372, and an electrical contact 314 on the upper faces of the third p-doped layer 313;

attaching S13 an electrical contact 38 on the exposed part of the base layer 36; and

depositing S14 a top distributed Bragg Reflector, top DBR, 315 on the third p-doped layer 313 in such a way that said DBR 315 at least overlies said central mesa region 311.

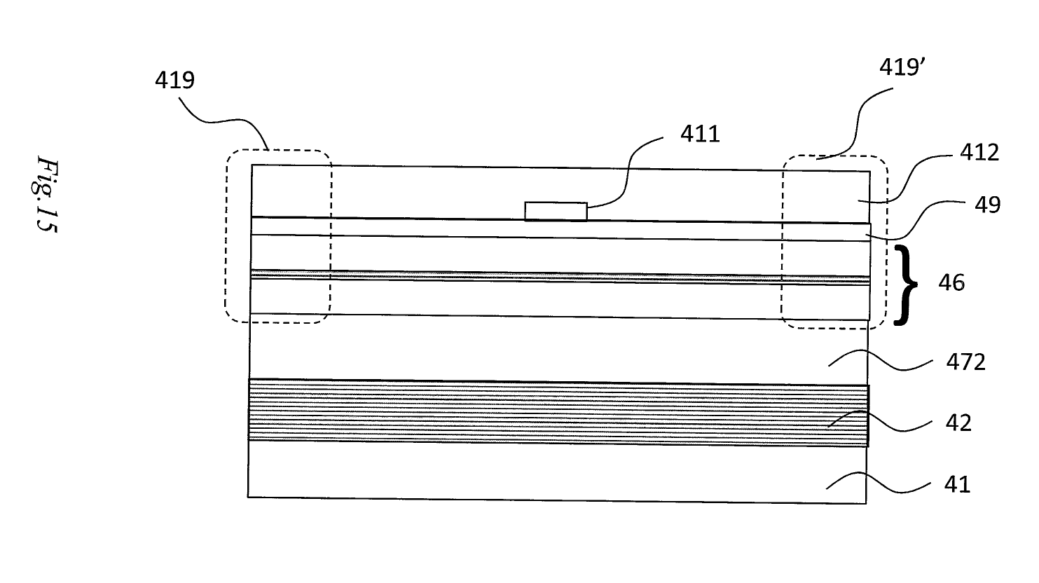

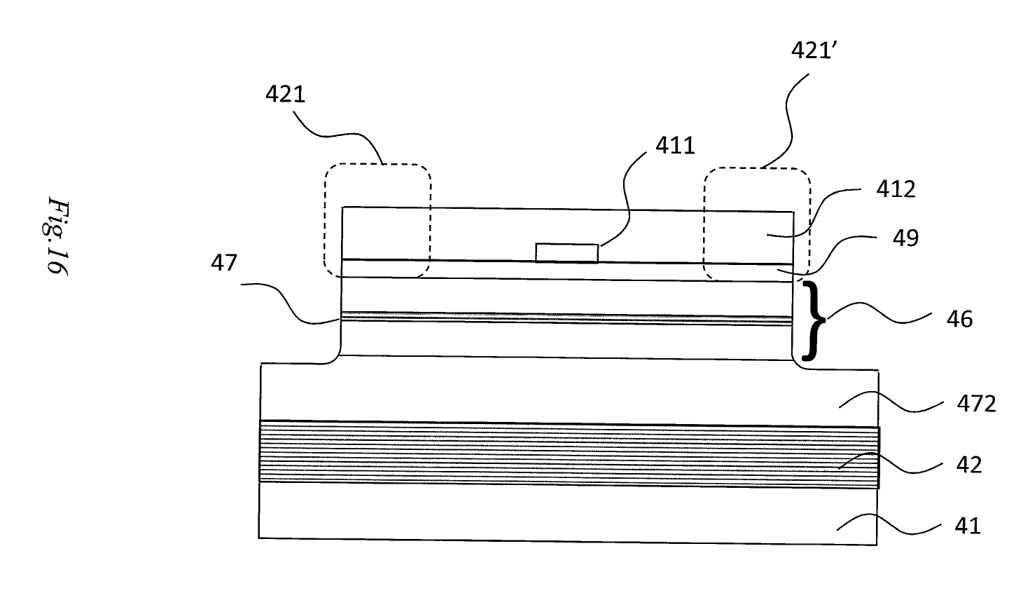

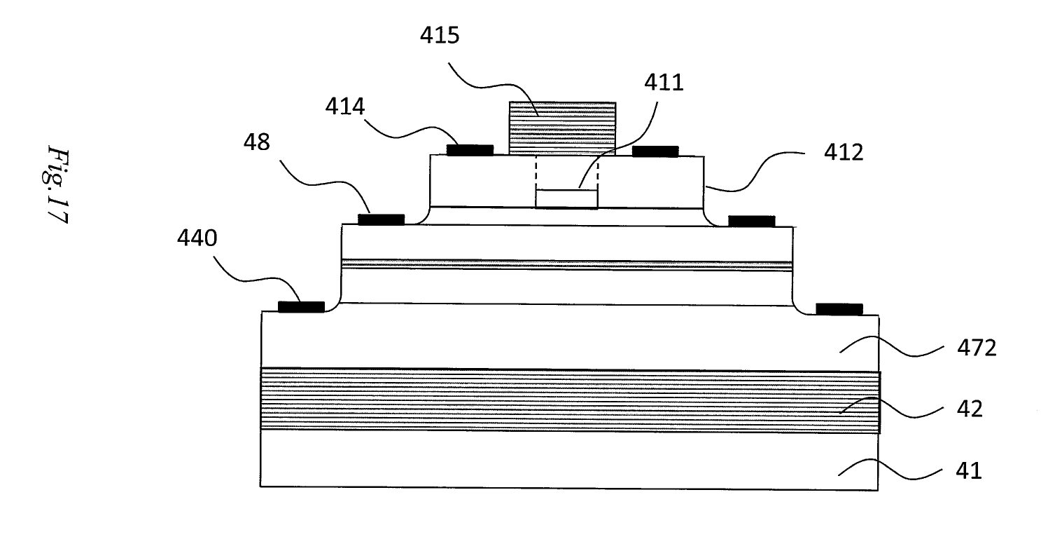

The fabrication of the T-VCSEL according to another embodiment of the invention is described with respect to FIGS. 14-17. First, the bottom DBR 42 is deposited on a substrate 41, after which part of the cavity consisting of layers 472, 46 and 49 (also corresponding to the collector region 472, base 46 and emitter region 49), including the light-emitting active layer 47 of the base 46 are provided on the bottom DBR. Thereafter a tunnel junction n⁺p⁺-bilayer 411′ is added and a central mesa region 411 is formed by etching away the volume corresponding to area 417, 417′. This is schematically illustrated in FIG. 14. A possible but not essential step S131 could also be added to the method in order to add an extra n-type layer 416 on top of the n⁺p⁺-bilayer 411′, this layer is not shown in FIG. 14. After the bilayer 411′ has been added and a central mesa region 411 been obtained through etching this is followed by an epitaxial regrowth step of an n-type semiconductor layer 412. Thereafter, the volumes 419 and 419′ are removed by etching to expose part of the layer 472. This is illustrated in FIG. 15. After that, as shown in FIG. 16, the volumes corresponding to 421 and 421′ are removed by means of etching, thus exposing part of the layer 46. The layer 46 corresponds to the base section 16 in FIGS. 1-8. After that an emitter contact 414 are formed on layer 412, a collector contact 440 is formed on the exposed part of the surface 472 and a base contact 48 is formed on the exposed part of the layer 46. Thereafter, the top DBR 115 is deposited on the regrown layer 412, in a way so that the DBR is at least overlying the central mesa region but could also overlie part of the peripheral region of the layer 412. The end product is schematically illustrated in FIG. 17.

In other words there is provided a method for producing T-VCSEL comprising the following steps:

depositing S1 a bottom Distributed Bragg Reflector, bottom DBR, 42, on a substrate 41;

depositing S2, on the bottom DBR 42, a p-doped collector layer 472;

depositing S3 a base layer 46, part of which is n-doped and comprises a light-emitting active layer 47, on top of the p-doped collector layer 472;

depositing S120 a p-doped layer 49 on top of the base layer 46;

depositing S130 an n+p+-tunnel-junction bilayer 411′ on top of the p-doped layer 49;

etching S140 away a volume 417, 417′ through said n⁺p⁺-tunnel-junction bilayer 411′, thereby creating a central mesa region 411;

growing S150, by epitaxial regrowth, an n-doped layer 412 on the peripheral region of the layer 49 and on top of the central mesa region 411;

etching S160 away a volume 419, 419′ through the n-doped layer 412, the p-doped layer 49, the base layer 46 and partly through the p-doped collector layer 472, thereby exposing part of the p-doped collector layer 472; and

etching S170 away a volume 421, 421′ through the n-doped layer 412, the p-doped layer 49 and partly through the base layer 46 above the light-emitting active region 47, thereby exposing part of the base layer 46;

attaching S180, an electrical contact 440 on the exposed part of the p-doped collector layer 472, and an electrical contact 414 on the upper faces of the n-doped layer 412;

attaching S190 an electrical contact 48 on the exposed part of the base layer 46; and

depositing S200 a top DBR 415 on the n-doped layer 412 in such a way that it at least overlies the central mesa region 411.

The method could also comprise a further step S2″ following the step S2 in order to add a forward-biased tunnel junction in a layer arranged between layers 472 and 46. It would be obvious for a person skilled in the art to alter the various doping type of the layers to accommodate such a forward-biased tunnel junction.

The fabrication methods described above, with reference to drawings 9-13 and 14-17, respectively, would work equally well if all doping types were reversed. That is all layers with a p-type of doping were replaced with layers of an n-type at the same time as layers with an n-type doping were replaced with layers with a p-type doping.

The attached electrical contacts above could be either p-type for 314, corresponding to the emitter contact, and for 340, corresponding to the collector contact, and n-type for 38, corresponding to the base contact, or vice versa.

As is clear from the above description the method steps S1, S2 and S3 are common for the methods described.

The fabrication sequence of the device is such that the cavity region is exposed before the final regrowth and/or deposition of the top DBR, thus making it possible to engineer the cavity shape for improved optical mode control, e.g. as discussed by X. Yu et al, Proc. SPIE 7720, 772021 (2010). The etching depth for mesa formation and/or regrowth thicknesses can also be chosen for a lateral variation of the cavity thickness, e.g., to focus the laser light to the central region, possibly through the spontaneous formation into a convex-shaped lens of the topmost regrown layer.

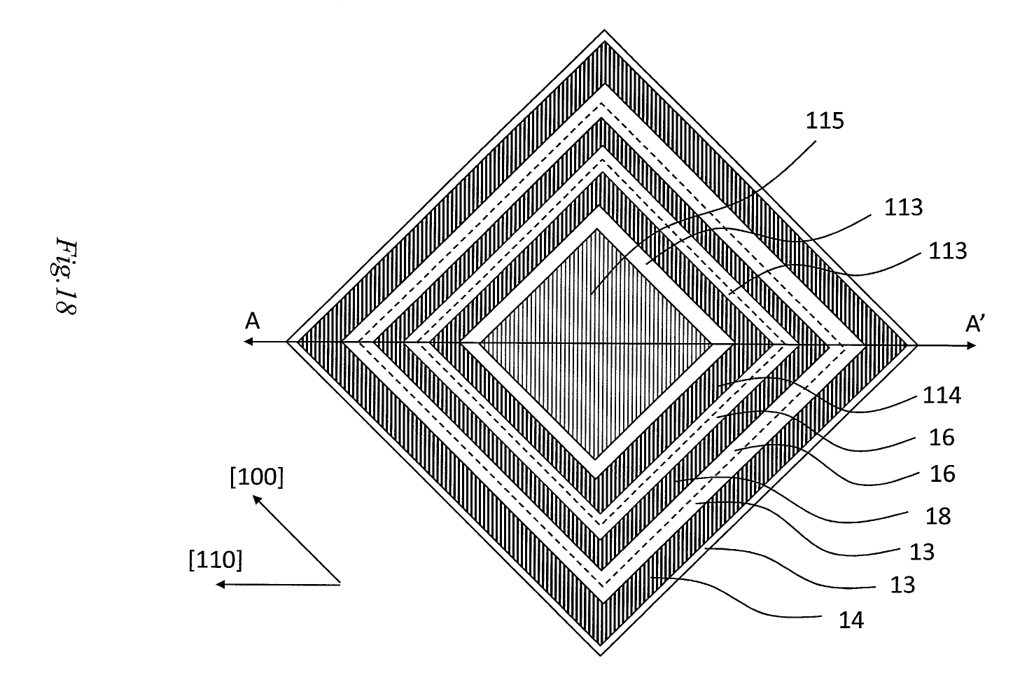

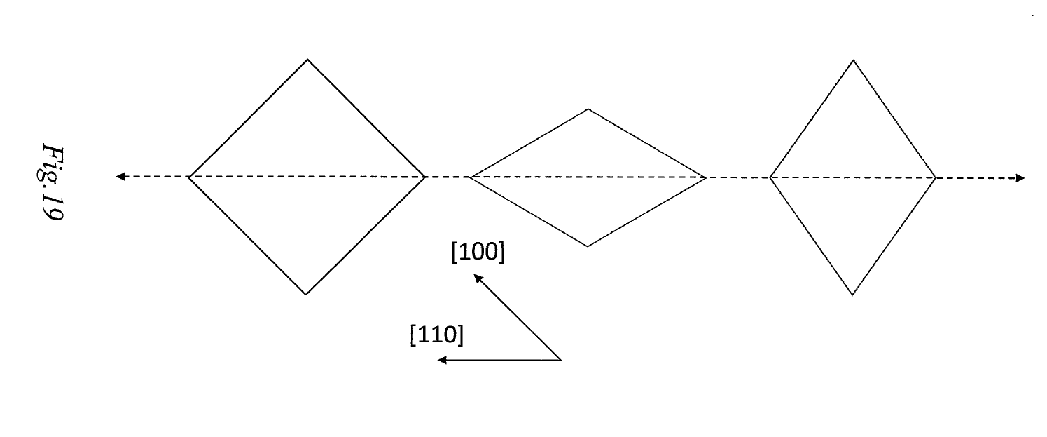

FIG. 18 shows a top view of an exemplary embodiment according to the invention. The line A-A′ denotes the cross-section shown in the corresponding figures. Assuming a semiconductor substrate in the zincblende structure with (001) surface orientation, such as GaAs or InP, the [001] and [011] crystallographic directions are indicated. The mesa structure with the top DBR is labelled 115. Outside the mesa structure, the second regrown layer 113 is indicated on both sides of the emitter contact 114 while the top surface of the base layer 16 is seen at both sides of the base contact 18. Similarly, the collector layer 172 is seen at both sides of the collector contact 14. FIG. 19 shows three different geometric forms of the mesa structure, with the crystallographic [001] and [011] directions indicated.

The shape of the mesa around which the regrowth is done is very important. This is due to the anisotropic properties of the mesa. Growth around a circular mesa proceeds with very different speeds in different crystallographic directions, causing very non-uniform regrowth shapes. Instead, the mesa is made square-shaped with sidewalls parallel with the [011] crystallographic directions of the substrate. Regrowth around such a mesa produces desirable regrowth shapes. One drawback with the square mesa is that it is invariant to a 90 degree rotation. This means that the laser light will not have any preferred polarization direction as both polarizations (which are rotated by 90 degree with respect to each other) will be influenced equally by the square mesa. In order to introduce anisotropy into the mesa shape, it can be made slightly rhombic with the sidewalls facing a few degrees off from the [011]-like directions. The regrowth shape around such a mesa does not differ from the regrowth shape around a perfectly square-shaped mesa.

The invention has been described with reference to exemplary embodiments but is not limited to those embodiments. Various modifications or alternations of the embodiments can easily be made by those skilled in the art without departing from the scope of the invention. It should for example be noted that the present invention lends itself equally well to alternative materials systems, such as InP, which is difficult to realize as based on selective oxidation that otherwise is a popular technology for GaAs-based conventional VCSELs. Thereby it is also suitable for a broad range of emission wavelengths, from the visible throughout the near-infrared communication wavelengths, e.g., including but not limited to 850, 1310, 1490 and 1550 nm.

### REFERENCES

1. N. Holonyak and M. Feng, “The transistor laser”, IEEE Spectrum 43 (2), 50 (2006).
2. J. Katz et al., “A monolithic integration of GaAs/AlGaAs bipolar transistor and heterostructure laser”, Appl. Phys. Lett., 37, 211 (1980).
3. M. Feng et a., “Resonance-free frequency response of a semiconductor laser”, Appl. Phys. Lett. 95, 033509 (2009).
4. H. W. Then et al., “Physics of base charge dynamics in the three port transistor laser”, Appl. Phys. Lett. 96, 113509 (2010).
5. B. Faraji et al, “Analytical modeling of the transistor laser”, IEEE J. Sel. Top. Quantum Electron. 15 (3), 594 (2009).
6. T. Tan et al., “Transistor laser with simultaneous electrical and optical output at 20 and 40 Gb/s data rate modulation”, Appl. Phys. Lett. 99, 061105 (2011).
7. M. Shirao et al., “Large-signal analysis of a transistor laser”, IEEE J. Quantum Electron. 47, 359 (2011).
8. I. Taghavi et al., “Bandwidth enhancement and optical performances of multiple quantum well transistor lasers”, Appl. Phys. Lett. 100, 231114 (2012).
9. F. Tan et al., “Relative intensity noise of a quantum well transistor laser”, Appl. Phys. Lett. 101, 151118 (2012)
10. E. W. Iverson and M. Feng, “Transistor laser power stabilization using direct collector current feedback control”, Photon. Technol. Lett. 24, 4 (2012).
11. B. Faraji et al., “Modelling the effect of the feedback on the small signal modulation of the transistor laser”, 23rd annual meeting of the IEEE Photonics Society, p. WX4, Denver Colo., Nov. 7-11 (2010).
12. H. W. Then et al., “Transistor laser optical and electrical linearity enhancement with collector current feedback”, Appl. Phys. Lett. 100, 221104 (2012).
13. A. M. Joshi et al., “Multilevel modulation formats push capacities beyond 100 Gbit/s”, Laser Focus World, February 2012, p. 58
14. W. Shi et al., “Numerical study of the optical saturation and voltage control of a transistor vertical-cavity surface-emitting laser”, IEEE Photonics Technol. Lett. 20 (24), 2141 (2008).
15. B. Faraji et al, “Common-emitter and common-base small-signal operation of the transistor laser”, Appl. Phys. Lett. 93, 143503 (2008).
16. See, e.g., H.n W. Then et al., “Electrical-optical signal mixing and multiplication (2→22 GHz) with a tunnel junction transistor laser”, Appl. Phys. Lett. 94, 101114 (2009).
17. P. Westbergh et al., “High-speed 850 nm VCSELs with 28 GHz modulation bandwidth operating error-freeup to 44 Gbit/s”, Electeron. Lett. 48 (18), 1145 (2012).
18. D. M. Kuchta et al., “A 55 Gb/s directly modulated 850 nm VCSEL-based Optical Link”, IEEE Photonics Conf. 2012 (IPC 2012), Post Deadline paper 1.5.
19. W. Shi et al., “Design and modeling of a transistor vertical-cavity surface-emitting laser”, Opt. Quantum Electron. 42, 659 (2011).
20. M-.K. Wu et al., “Surface emission vertical cavity transistor laser”, Photon. Technol. Lett. 24 (15), 1346 (2012).
21. M-.K. Wu et al., “Voltage modulation of a vertical cavity transistor laser via intra-cavity photon-assisted tunneling”, Appl. Phys. Lett. 101, 081102 (2012).
22. M. K. Wu et al., “Selective oxidation cavity confinement for low threshold vertical cavity transistor lasers”., Appl. Phys. Lett. 103, 011104 (2013).
23. Y. Onishi et al., IEEE J. Sel. Top. Quantum Electron, 15 (3), 838 (2009)
24. R. M. Marcks von Würtemberg et al, IET Optoelectronics, 3 (2), 112 (2009).
25. X. Yu et al, Proc. SPIE 7720, 772021 (2010)

1. A transistor vertical-cavity surface-emitting laser, T-VCSEL, comprising:
a collector section having a bottom substrate and a base contacting layer, defining a collector region;
an emitter section; and
a base section, arranged between the emitter section and the collector section, and having a collector contacting layer and a light emitting active layer, arranged between layers of a base material;
wherein the emitter section has a current confining blocking layer including
a first material layer, having a first type of doping and a current confining region, and
a second material layer, defining an emitter region, having a second type of doping and being provided on a base side of the first material layer;
whereby electrical carriers injected from the emitter section flow through the current confining blocking layer confined by the current confining region to arrive at the base section to thereby activate the light emitting active layer.

2. The T-VCSEL according to claim 1, wherein the first and the second material layers are layers of a semi-conducting material.

3. The T-VCSEL according to claim 1, wherein the first material layer comprises an n-doped material layer and the second material layer comprises a p-doped material layer.

4. The T-VCSEL according to claim 1, wherein the current confining blocking layer includes a third material layer arranged on the first material layer on the side farthest from the base section where the third material layer has the same doping type as the second material layer.

5. The T-VCSEL according to claim 4, wherein the current confining region comprises a square-shaped section extending through the first material layer, and containing at least part of the third material layer to thereby confine carriers injected from the emitter section to the base section to flow in the square-shaped section.

6. The T-VCSEL according to claim 3, wherein the material of the first material layer is GaAs, the material of the second material layer is AlGaAs and the material of the third material layer is GaAs.

7. The T-VCSEL according to claim 1, wherein the light emitting active layer in the base section comprises a multilayered InGaAs/GaAs triple quantum well active layer, with alternating InGaAs layers and GaAs layers, arranged between layers of the base material that is an n-doped GaAs material and provided on top of the collector contacting layer.

8. The T-VCSEL according to claim 1, wherein the base contacting layer of the collector section is a p-doped GaAs layer, and wherein the collector contacting layer of the base section is a GaAs layer.

9. The T-VCSEL according to claim 1, wherein the second material layer is provided with a reduced or non-uniform doping concentration that is higher closer to the base section.

10. The T-VCSEL according to claim 2, wherein the current confining region comprises an n⁺p⁺ tunnel junction buried in the first material layer and connecting the first material layer to the second material layer, thus providing carrier injection from the emitter section to the base section.

11. The T-VCSEL according to claim 10, wherein the first material layer comprises an n-doped layer and the second material layer comprises a p-doped layer.

12. The T-VCSEL according to claim 11, wherein the first material layer is a GaAs-layer and the second material layer is an InGaP-layer.

13. The T-VCSEL according to claim 10, wherein the light emitting active layer in the base section comprises an InGaAs/GaAs triple quantum well active layer, with alternating InGaAs layers and GaAs layers arranged between layers of the base material of an n-doped GaAs material, and is provided on top of the collector contacting layer.

14. The T-VCSEL according to claim 13, wherein the base contacting layer of the collector section is a p-doped GaAs layer, and wherein the collector contacting layer of the base section is a GaAs layer.

15. The T-VCSEL according to claim 14, further comprising a p⁺n⁺ tunnel junction arranged between the collector contacting layer the base contacting layer.

16. The T-VCSEL according to claim 13, wherein the collector contacting layer is a GaAs layer, and wherein the base contacting layer is an n-doped GaAs layer.

17. The T-VCSEL according to claim 1, wherein the collector section comprises a multi-layered distributed Bragg reflector, DBR, provided between the bottom substrate and the base contacting layer.

18. The T-VCSEL according to claim 17, wherein the DBR comprises a multi-layered structure with alternating AlGaAS layers and GaAs layers.

19. The T-VCSEL according to claim 1, wherein the emitter section comprises a multi-layered distributed Bragg reflector, DBR, arranged on the current confining blocking layer on the side farthest from the base section.

20. The T-VCSEL according to claim 19, wherein the DBR comprises a-Si layers alternated with SiO₂ layers.

21. The T-VCSEL according to claim 1, wherein he bottom substrate of the collector section comprises a GaAs substrate.

22. The T-VCSEL according to claim 2, wherein the first material layer comprises a p-doped material layer and the second material layer comprises an n-doped material layer.

23. The T-VCSEL according to claim 1, further comprising:
an emitter contact, corresponding to a first terminal arranged on the emitter section;
a base contact, corresponding to a second terminal, arranged on the base section; and
a collector contact, corresponding to a third terminal, arranged on the collector section.

24. A method for producing a transistor vertical-cavity surface-emitting laser, T-VCSEL, the method comprising:
depositing a bottom distributed Bragg reflector, bottom DBR, on a substrate;
depositing, on the bottom DBR, a p-doped collector layer;
depositing a base layer, part of which is n-doped and comprises a light-emitting active layer, on top of the p-doped collector layer;
depositing a first p-doped layer and a second p-doped layer on top of the base layer;
etching away a volume through the second p-doped layer, thereby creating a central mesa region;
covering the central mesa region with a masking material preventing epitaxial regrowth;
growing, by epitaxial regrowth, an n-doped layer on a peripheral region of the first p-doped layer surrounding the central mesa region;
removing the masking material from the top of the central mesa region;
growing, by epitaxial regrowth, a third p-doped layer over both the central mesa region and the n-doped layer;
etching away a volume through the third p-doped layer, the n-doped layer, the first p-doped layer, the base layer and partly through the p-doped collector layer, thereby exposing part of the p-doped collector layer;
etching away a volume through the third p-doped layer, the n-doped layer, the first p-doped layer and partly through the base layer above the light-emitting active layer, thereby exposing part of the base layer;
attaching an electrical contact on the exposed part of the p-doped collector layer, and an electrical contact on the third p-doped layer;
attaching an electrical contact on the exposed part of the base layer; and
depositing a top distributed Bragg reflector, top DBR, on the third p-doped layer in such a way that the top DBR at least overlies the central mesa region.

25. A method for producing a transistor vertical-cavity surface-emitting laser, T-VCSEL, the method comprising:
depositing a bottom distributed Bragg reflector bottom DBR, on a substrate;
depositing, on the bottom DBR, a p-doped collector layer;
depositing a base layer, part of which is n-doped and comprises a light emitting active layer, on top of the p-doped collector layer;
depositing a p-doped layer on top of the base layer;
depositing an n⁺p⁺ tunnel-junction bilayer on top of the p-doped layer;
etching away a volume through the n⁺p⁺-tunnel-junction bilayer, thereby creating a central mesa region;
growing, by epitaxial regrowth, an n-doped layer on a peripheral region of the p-doped layer and on top of the mesa region;
etching away a volume through the n-doped layer, the p-doped layer, the base layer and partly through the collector layer, thereby exposing part of the collector layer; and
etching away a volume through the n-doped layer, the p-doped layer and partly through the base layer above the light-emitting active layer, thereby exposing part of the base layer;
attaching, an electrical contact on the exposed part of the collector layer, and an electrical contact on the n-doped layer;
attaching an electrical contact on the exposed part of the base layer; and
depositing a top distributed Bragg reflector, top DBR, on the n-doped layer, in such a way that the top DBR at least overlies the central mesa region.
